(19) United States
(12) Patent Application Publication
(10) Pub. No.: US 2026/0333587 A1
(43) Pub. Date: Oct. 22, 2026

(54) PRINTED CIRCUIT BOARD

(71) Applicant: SAMSUNG ELECTRO-MECHANICS CO., LTD., Suwon-si (KR)

(72) Inventors: Jae Woong CHOI, Suwon-si (KR); Seung Eun LEE, Suwon-si (KR)

(73) Assignee: SAMSUNG ELECTRO-MECHANICS CO., LTD., Suwon-si (KR)

(21) Appl. No.: 19/453,072

(22) Filed: Jan. 20, 2026

(30) Foreign Application Priority Data
Apr. 22, 2025 (KR) 10-2025-0052211
Jul. 22, 2025 (KR) 10-2025-0098992

(51) Int. Cl. H05K 1/185; H05K 1/03; H05K 1/11

(52) U.S. Cl. CPC H05K 1/185; H05K 1/0366; H05K 1/0373; H05K 1/115; H05K 2201/096; H05K 2201/10015

(57) ABSTRACT

A printed circuit board comprises a core portion having a core layer, a first insulating layer with a plurality of first wiring layers, and a second insulating layer with a plurality of second wiring layers; a first build‑up portion having a first build‑up layer with a plurality of third wiring layers; and a second build‑up portion having a second build‑up layer with a plurality of fourth wiring layers. A first electronic component is embedded within the core portion. A second electronic component is embedded within the core portion or within the first build‑up portion at a level different from the first electronic component. At least one of the first insulating layer or the second insulating layer is formed of an insulating material different from that of at least one of the first build‑up layer or the second build‑up layer.

### CROSS-REFERENCE TO RELATED APPLICATIONS

This application claims benefit of priority to Korean Patent Application No. 10-2025-0098992 filed on July 22, 2025 and Korean Patent Application No. 10-2025-0052211 filed on April 22, 2025, in the Korean Intellectual Property Office, the disclosures of which are incorporated herein by reference in their entireties.

### BACKGROUND

### 1. FIELD

The present disclosure relates to a printed circuit board.

### 2. Description of Related Art

As servers for high‑performance computing, artificial intelligence, and advanced networking scale, speed, bandwidth, and dynamic power consumption rise, increasing the difficulty of maintaining stable power delivery during chip design and packaging. Rapid load transients (high di/dt), voltage droop, and simultaneous switching noise are amplified by interconnect inductance and routing complexity. Embedding devices within the substrate can shorten current paths and improve power integrity, but embedding alone—without coordinated stack‑up design and material selection—cannot meet stringent capacitance density and impedance targets across the relevant frequency band. Thus, there is a need for new and improved co‑optimized substrate and power‑delivery network (PDN)/architecture that uses, for example, low‑loss core layers with tightly spaced power/ground planes, high‑k thin‑film build‑up layers for dense embedded decoupling, short parallel microvias to minimize loop inductance, depth‑staggered placement of active/passive devices, and power‑integrity co‑simulation to hold the PDN below target impedance and avoid anti‑resonance.

### SUMMARY

An aspect of the present disclosure is to provide a printed circuit board that can be applied to a large body product, and have sufficient capacitance as required.

One of the various solutions proposed by the present disclosure includes embedding a first electronic component in a core portion of a multilayer structure, stacking a build-up portion on the core portion, and embedding a second electronic component, disposed on a different level from that of the first electronic component in the core portion and/or the build-up portion. In this case, the first electronic component may include a multilayer ceramic capacitor, and the second electronic component may include a silicon capacitor, but an embodiment thereof is not limited thereto.

According to an aspect of the present disclosure, a printed circuit board may include a core portion including a core layer, a first insulating layer, at least partially disposed on an upper side of the core layer, a plurality of first wiring layers respectively disposed on or within the first insulating layer, a second insulating layer, at least partially disposed on a lower side of the core layer, and a plurality of second wiring layers respectively disposed on or within the second insulating layer; a first build-up portion including a first build-up layer disposed on the upper side of the core portion, and a plurality of third wiring layers respectively disposed on or within the first build-up layer; a second build-up portion including a second build-up layer disposed on the lower side of the core portion, and a plurality of fourth wiring layers respectively disposed on or within the second build-up layer; a first electronic component embedded in the core portion; and a second electronic component embedded in at least one of the core portion or the first build-up portion, on a different level from that of the first electronic component, wherein at least one of the first insulating layer or the second insulating layer may include a different insulating material from at least one of the first build-up layer or the second build-up layer.

According to an aspect of the present disclosure, a printed circuit board may include a core layer having a first cavity; a plurality of through-vias respectively penetrating through at least a portion of the core layer; an insulating layer disposed on the core layer, and having a second cavity; a multilayer ceramic capacitor disposed in the first cavity, and embedded in the insulating layer; a silicon capacitor disposed in the second cavity, and embedded in the insulating layer; a plurality of wiring layers respectively disposed within the insulating layer; and a plurality of wiring vias respectively penetrating through at least a portion of the insulating layer, wherein the first cavity and the second cavity may be disposed on different levels.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional view schematically illustrating an example of a printed circuit board;

FIG. 2 is a cross-sectional view schematically illustrating a modified example of a printed circuit board;

FIG. 3 illustrates a manufacturing example of a core portion;

FIG. 4 illustrates a manufacturing example of a core portion;

FIG. 5 is a cross-sectional view schematically illustrating another example of a printed circuit board;

FIG. 6 is a cross-sectional view schematically illustrating another modified example of a printed circuit board; and

FIG. 7 is a cross-sectional view schematically illustrating another example of a printed circuit board.

### DETAILED DESCRIPTION

Hereinafter, the present disclosure will be described with reference to the attached drawings. The shapes and sizes of elements in the drawings may be exaggerated or reduced for clearer description.

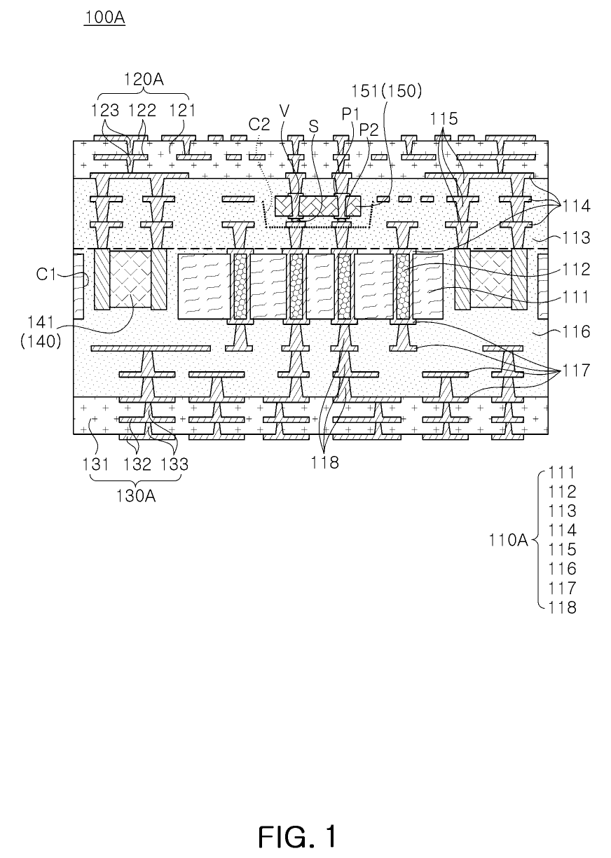

FIG. 1 is a cross-sectional view schematically illustrating an example of a printed circuit board.

Referring to FIG. 1, a printed circuit board 100A according to an example may include a core portion 110A, a first build-up portion 120A disposed on an upper side of the core portion 110A, a second build-up portion 130A disposed on a lower side of the core portion 110A, a first electronic component 140 embedded in the core portion 110A, and a second electronic component 150 embedded in the core portion 110A on a different level from that of the first electronic component 140. The core portion 110A may include a core layer 111, a plurality of through-vias 112 respectively disposed within the core layer 111, a first insulating layer 113, at least partially disposed on the upper side of the core layer 111, a plurality of first wiring layers 114 respectively disposed on or within the first insulating layer 113, a plurality of first wiring vias 115 respectively disposed within the first insulating layer 113, a second insulating layer 116, at least partially disposed on the lower side of the core layer 111, a plurality of second wiring layers 117 respectively disposed on or within the second insulating layer 116, and a plurality of second wiring vias 118 respectively disposed within the second insulating layer 116. The first build-up portion 120A may include a first build-up layer 121, a plurality of third wiring layers 122 respectively disposed on or within the first build-up layer 121, and a plurality of third wiring vias 123 respectively disposed within the first build-up layer 121. The second build-up portion 130A may include a second build-up layer 131, a plurality of fourth wiring layers 132 respectively disposed on or within the second build-up layer 131, and a plurality of fourth wiring vias 133 respectively disposed within the second build-up layer 131. The first electronic component 140 may include a multilayer ceramic capacitor 141, a chip inductor, and/or an active die, and may for example, include at least a multilayer ceramic capacitor 141. The second electronic component 150 may include a silicon capacitor 151.

As described above, the printed circuit board 100A according to an example may include a core portion 110A having a multi-layer core (MLC) structure, and may have a multi-layer package substrate structure in which the first and second build-up portions 120A and 130A are stacked on both sides of the core portion 110A. Therefore, the printed circuit board 100A may be easily applied to a large-body product such as a server package substrate, or the like. In addition, since wiring design may be precisely performed, the problem of electromigration (EM) may be reduced. In addition, a pitch of the plurality of through-vias 112 formed in the core layer 111 may be reduced. In addition, a pitch of the plurality of through-vias 112 formed in the core layer 111 may be reduced. In addition, the first electronic component 140 and the second electronic component 150 may be embedded in different levels of the core portion 110A, respectively, and in this case, each of the first electronic component 140 and the second electronic component 150 may include a multilayer ceramic capacitor 141 and a silicon capacitor 151. For example, in addition to embedding the silicon capacitor 151, the multilayer ceramic capacitor 141 may be embedded together. Therefore, capacitance thereof may be increased, which can facilitate response to application products requiring high power consumption.

Meanwhile, the first insulating layer 113 and/or the second insulating layer 116 may include a different insulating material from the first build-up layer 121 and/or the second build-up layer 131. For example, the core layer 111, the first insulating layer 113, and the second insulating layer 116 may include an insulating resin, a filler, and glass fiber, while the first build-up layer 121 and the second build-up layer 131 may include an insulating resin and a filler but may not include glass fiber. For example, the core layer 111 may include an insulating material of a copper clad laminate (CCL), each of the first insulating layer 113 and the second insulating layer 116 may include a prepreg (PPG), and each of the first build-up layer 121 and the second build-up layer 131 may each include an Ajinomoto Build‑up Film (ABF). In this case, resistance to warpage and thermal expansion of a substrate may be improved through the core portion 110A, and fine routing and high-density wiring design may be performed through the first and/or second build-up portions 120A and 130A. Therefore, a structure, suitable for a high-reliability, high-performance package substrate may be easily implemented.

Meanwhile, the core layer 111 may have a first cavity (C1) penetrating between an upper surface and a lower surface of the core layer 111 in a thickness direction. A first electronic component 140, such as a multilayer ceramic capacitor 141, may be disposed in the first cavity (C1). The first insulating layer 113 and/or the second insulating layer 116 may fill at least a portion of the first cavity (C1) and cover at least a portion of the first electronic component 140, such as a multilayer ceramic capacitor 141. If necessary, when a separate insulating material is used to fill the first cavity (C1), the insulating material may be considered a portion of the first insulating layer 113 and/or the second insulating layer 116. The first cavity (C1) may be formed in plural. The plurality of first cavities (C1) may be disposed at the same level. A first electronic component 140, for example, a multilayer ceramic capacitor 141, may be disposed in the plurality of first cavities (C1), respectively, a first insulating layer 113 and/or a second insulating layer 116, may fill at least a portion of each of the plurality of first cavities (C1), and the first insulating layer 113 and/or the second insulating layer 116 may cover at least a portion of the first electronic component 140, such as a multilayer ceramic capacitor 141, disposed in each of the plurality of first cavities (C1). The first electronic component 140, such as a multilayer ceramic capacitor 141, may be easily embedded through the first cavity (C1). Each first electronic component 140, for example, each multilayer ceramic capacitor 141 may have an external electrode connected to at least one first wiring via 115, thereby being electrically connected to at least a portion of the plurality of first wiring layers 114. However, an embodiment thereof is not limited thereto, and if necessary, each first electronic component 140, for example, each multilayer ceramic capacitor 141 may have an external electrode connected to at least one second wiring via 118, thereby being electrically connected to at least a portion of the plurality of second wiring layers 117. For example, each first electronic component 140, for example, each multilayer ceramic capacitor 141, may be electrically connected to the upper side and/or lower side.

Meanwhile, the first insulating layer 113 may have a second cavity (C2) penetrating through at least a portion of the first insulating layer 113 in the thickness direction. A position of the second cavity (C2) is not particularly limited, and may be formed at various positions within the first insulating layer 113. A second electronic component 150, for example, a silicon capacitor 151 may be disposed in the second cavity (C2). The first insulating layer 113 may fill at least a portion of the second cavity (C2) and cover at least a portion of the second electronic component 150, for example, the silicon capacitor 151. If necessary, a separate insulating material may be used to fill the second cavity (C2), which may be considered a portion of the first insulating layer 113. The second electronic component 150 may be easily embedded through the second cavity (C2). A first pad P1 of the second electronic component 150, for example, the silicon capacitor 151, may be connected to at least one first wiring via 115, thereby being electrically connected to at least a portion of the plurality of first wiring layers 114. In addition, a second pad P2 of the second electronic component 150, for example, the silicon capacitor 151, may be connected to a conductive bump (S), thereby being electrically connected to at least another portion of the plurality of first wiring layers 114.

Meanwhile, the silicon capacitor 151 may include a silicon through-via (V). The silicon through-via (V) may be connected to at least one of the plurality of through-vias 112. Therefore, even when embedding a silicon capacitor 151 above the core layer 111, the problem of loss of function or deterioration of function of at least one of the plurality of through-vias 112 may be prevented. Therefore, signal integrity and power integrity may be easily maintained and/or improved. For example, the silicon capacitor 151 may include a silicon through-via (V), a first pad P1 connected to an upper side of the silicon through-via (V), and a second pad P2 connected to a lower side of the silicon through-via (V), and in this case, the first pad P1 may be electrically connected to at least a portion of the plurality of first wiring layers 114 through at least one first wiring via 115, and the second pad P2 may be electrically connected to at least another portion of the plurality of first wiring layers 114 through a conductive bump (S). Accordingly, upper and lower electrical connection paths may be easily provided even in a region in which the silicon through-via 151 is disposed. At least another portion of the plurality of first wiring layers 114 connected to the conductive bump (S) may be disposed on a bottom surface of the second cavity (C2), and may be electrically connected to at least a portion of the plurality of through-vias 112. The silicon capacitor 151 may include a plurality of silicon through-vias (V) and a plurality of first and second pads P1 and P2, and the above-described contents may be applied to each of the plurality of silicon through-vias (V) and the plurality of first and second pads P1 and P2.

Meanwhile, each of the first insulating layer 113, the second insulating layer 116, the first build-up layer 121, and the second build-up layer 131 may be comprised of a plurality of layers. For example, each of the first insulating layer 113, the second insulating layer 116, the first build-up layer 121, and the second build-up layer 131 may be comprised of a plurality of insulating layers. The plurality of insulating layers constituting the first insulating layer 113 may have unclear boundaries, but interlayer boundaries thereof may be distinguished. The plurality of insulating layers constituting the second insulating layer 116 may have unclear boundaries, but interlayer boundaries thereof may be distinguished. The plurality of insulating layers constituting the first build-up layer 121 may have unclear boundaries with each other, but interlayer boundaries thereof may be distinguished. The plurality of insulating layers constituting the second build-up layer 131 may have unclear boundaries with each other, but interlayer boundaries thereof may be distinguished. In each of the first insulating layer 113, the second insulating layer 116, the first build-up layer 121, and the second build-up layer 131, when the interlayer boundaries of the plurality of insulating layers are unclear, the layers may be distinguished through the plurality of wiring layers and/or the plurality of wiring vias formed in the plurality of insulating layers. When each of the first insulating layer 113, the second insulating layer 116, the first build-up layer 121, and the second build-up layer 131 is comprised of a plurality of layers, more various wiring design may be performed. If necessary, the first insulating layer 113, the second insulating layer 116, the first build-up layer 121, and the second build-up layer 131 may be combined and referred to as a single insulating layer. Similarly, the plurality of first wiring layers 114, the plurality of second wiring layers 117, the plurality of third wiring layers 122, and the plurality of fourth wiring layers 132 may be combined and referred to as a plurality of wiring layers. Similarly, the plurality of first wiring vias 115, the plurality of second wiring vias 118, the plurality of third wiring vias 123, and the plurality of fourth wiring vias 133 may be combined and referred to as a plurality of wiring vias.

Hereinafter, components of the printed circuit board 100A according to an example will be described in more detail with reference to the drawings.

The core layer 111 may include an insulating material. The insulating material may include an insulating resin, such as a thermosetting resin such as an epoxy resin and/or a thermoplastic resin such as polyimide. In addition, the insulating material may include glass fiber (glass cloth, glass fabric) together with the insulating resin. In addition, the insulating material may include both an insulating resin, a filler, and glass fiber. For example, the core layer 111 may include an insulating material such as Copper Clad Laminate (CCL). However, the present disclosure is not limited thereto, and the core layer 111 may be a core layer including an inorganic insulating material such as a glass core, a ceramic core, or the like. Alternatively, it may be a metal core covered with an insulating film, or the like. A thickness of the core layer 111 may be greater than an insulating distance between any two first wiring layers 114 adjacent to each other in a thickness direction and/or an insulating distance between any two second wiring layers 117 adjacent to each other in the thickness direction. The core layer 111 may have a first cavity (C1) penetrating between the upper and lower surfaces of the core layer 111 in the thickness direction, and one or more first cavities (C1) may be formed.

The through-via 112 may include a metal material. The metal material may include copper (Cu), aluminum (Al), silver (Ag), tin (Sn), gold (Au), nickel (Ni), lead (Pb), titanium (Ti), and/or alloys thereof. The through-via 112 may perform various functions depending on a design. For example, the through-via 112 may include a ground via, a power via, a signal via, and the like. The through-via 112 may have a substantially circular or elliptical shape on a plane, and may have a substantially columnar or hourglass shape in cross-section, but an embodiment thereof is not limited thereto. The through-via 112 may be formed in a through-hole penetrating between the upper and lower surfaces of the core layer 111 in the thickness direction. For example, the through-via 112 may be a Plated Through Hole (PTH). The through-via 112 may include a sputtering layer (e.g., sputtering titanium/copper) and/or an electroless plating layer (e.g., chemical copper) as a seed layer, and may include an electrolytic plating layer (e.g., electrolytic copper) as a plating layer. The plating layer may be a fill plating layer or a conformal plating layer, and when the plating layer is a conformal plating layer, a filler may be filled therein. The filler may include a conductive paste, an insulating resin, or the like. The through-via 112 may be provided in plural, and the above-described content may be independently applied to each of the plurality of through-vias 112. The first wiring layer 114 at the lowermost layer and the second wiring layer 117 at the uppermost layer may be electrically connected to each other through the plurality of through-vias 112.

Each of the first and second insulating layers 113 and 116 may include an insulating material. The insulating material may include an insulating resin, such as a thermosetting resin, such as an epoxy resin, and/or a thermoplastic resin, such as polyimide. In addition, the insulating material may further include a filler, such as an inorganic filler and/or an organic filler, in addition to the insulating resin. In addition, the insulating material may include glass fiber (glass cloth, glass fabric) together with an insulating resin. In addition, the insulating material may include both an insulating resin, a filler, and glass fiber. For example, each of the first and second insulating layers 113 and 116 may include a prepreg (PPG). The first and second insulating layers 113 and 116 may include substantially the same insulating material, such as a prepreg (PPG), and in this case, the first and second insulating layers 113 and 116 may be integrated with each other without interlayer boundaries therebetween. When there are no interlayer boundaries between the first and second insulating layers 113 and 116 or the interlayer boundaries is unclear, the layers may be distinguished based on the outermost surface of the first electronic component 140. However, an embodiment thereof is not limited thereto, and interlayer boundaries between the first and second insulating layers 113 and 116 may be distinguished. Each of the first and second insulating layers 113 and 116 may be comprised of a plurality of insulating layers, and each insulating layer may include a prepreg (PPG). The plurality of insulating layers constituting the first insulating layer 113 may be integrated with each other without interlayer boundaries thereof, or may have unclear interlayer boundaries thereof. However, an embodiment thereof is not limited thereto, and the interlayer boundaries between the plurality of insulating layers constituting the first insulating layer 113 may be distinguished. The plurality of insulating layers constituting the second insulating layer 116 may be integrated with each other without interlayer boundaries thereof, or may have unclear interlayer boundaries thereof. However, an embodiment thereof is not limited thereto, and the interlayer boundaries between the plurality of insulating layers constituting the second insulating layer 116 may be distinguished.

Each of the first and second wiring layers 114 and 117 may include a metal material. The metal material may include copper (Cu), aluminum (Al), silver (Ag), tin (Sn), gold (Au), nickel (Ni), lead (Pb), titanium (Ti), and/or alloys thereof. The first and second wiring layers 114 and 117 may perform various functions depending on a design. For example, the first and second wiring layers 114 and 117 may include a signal pattern, a power pattern, and a ground pattern. Each of the patterns may have various forms such as a line, a plane, and a pad. Each of the first and second wiring layers 114 and 117 may include a sputtering layer (e.g., sputtering titanium/copper) and/or an electroless plating layer (e.g., chemical copper) as a seed layer, and may include an electrolytic plating layer (e.g., electrolytic copper) as a plating layer. Each of the first and second wiring layers 114 and 117 may be a plurality of layers, and the above-described contents may be independently applied to each of the first and second wiring layers 114 and 117.

Each of the first and second wiring vias 115 and 118 may include a metal material. The metal material may include copper (Cu), aluminum (Al), silver (Ag), tin (Sn), gold (Au), nickel (Ni), lead (Pb), titanium (Ti), and/or alloys thereof. Each of the first and second wiring vias 115 and 118 may include a filled via filling a via hole, but may also include a conformal via disposed along a wall surface of the via hole. Each of the first and second wiring vias 115 and 118 may perform various functions depending on a design. For example, the first and second wiring vias 115 and 118 may include a ground via, a power via, a signal via, and the like. Each of the first and second wiring vias 115 and 118 may include a sputtering layer (e.g., sputtering titanium/copper) and/or an electroless plating layer (e.g., chemical copper) as a seed layer, and may include an electrolytic plating layer (e.g., electrolytic copper) as a plating layer. Each of the first and second wiring vias 115 and 118 may have a shape tapered in opposite directions in cross-section. Each of the first and second wiring vias 115 and 118 may be provided in plural, and the above-described contents may be applied independently to each of the plurality of first and second wiring vias 115 and 118. A plurality of second wiring layers 117 may be electrically connected to each other through the plurality of second wiring vias 118.

Each of the first and second build-up layers 121 and 131 may include an insulating material. The insulating material may include an insulating resin, such as a thermosetting resin, such as an epoxy resin, and/or a thermoplastic resin, such as polyimide. In addition, the insulating material may further include a filler, such as an inorganic filler and/or an organic filler, in addition to the insulating resin. For example, the first and second build-up layers 121 and 131 may include an Ajinomoto Build-up Film (ABF). For example, each of the first and second build-up layers 121 and 131 may be comprised of a plurality of insulating layer, and in this case, each insulating layer may include an Ajinomoto Build-up Film (ABF).

Each of the third and fourth wiring layers 122 and 132 may include a metal material. The metal material may include copper (Cu), aluminum (Al), silver (Ag), tin (Sn), gold (Au), nickel (Ni), lead (Pb), titanium (Ti), and/or alloys thereof. The third and fourth wiring layers 122 and 132 may perform various functions depending on a design. For example, the third and fourth wiring layers 122 and 132 may include a signal pattern, a power pattern, and a ground pattern. Each of the patterns may have various forms such as a line, a plane, and a pad. Each of the third and fourth wiring layers 122 and 132 may include a sputtering layer (e.g., sputtering titanium/copper) and/or an electroless plating layer (e.g., chemical copper) as a seed layer, and may include an electrolytic plating layer (e.g., electrolytic copper) as a plating layer. Each of the third and fourth wiring layers 122 and 132 may be a plurality of layers, and the above-described contents may be independently applied to each of the third and fourth wiring layers 122 and 132.

Each of the third and fourth wiring vias 123 and 133 may include a metal material. The metal material may include copper (Cu), aluminum (Al), silver (Ag), tin (Sn), gold (Au), nickel (Ni), lead (Pb), titanium (Ti), and/or alloys thereof. Each of the third and fourth wiring vias 123 and 133 may include a filled via filling a via hole, but may also include a conformal via disposed along a wall surface of the via hole. Each of the third and fourth wiring vias 123 and 133 may perform various functions depending on a design. For example, the third and fourth wiring vias 123 and 133 may include a ground via, a power via, a signal via, and the like. Each of the third and fourth wiring vias 123 and 133 may include a sputtering layer (e.g., sputtering titanium/copper) and/or an electroless plating layer (e.g., chemical copper) as a seed layer, and may include an electrolytic plating layer (e.g., electrolytic copper) as a plating layer. Each of the third and fourth wiring vias 123 and 133 may have a shape tapered in opposite directions in cross-section. Each of the third and fourth wiring vias 123 and 133 may be provided in plural, and the above-described contents may be applied independently to each of the plurality of third and fourth wiring vias 123 and 133. A plurality of third wiring layers 122 may be electrically connected to each other through the plurality of third wiring vias 123, and also, the first wiring layer 114 at the uppermost layer and the third wiring layer 122 at the lowermost layer may be electrically connected to each other. A plurality of fourth wiring layers 132 may be electrically connected to each other through the plurality of fourth wiring vias 133, and also, the second wiring layer 117 at the lowermost layer and the fourth wiring layer 132 at the uppermost layer may be electrically connected to each other.

Each of the first and second electronic components 140 and 150 may include various types of active and/or passive components. For example, the first electronic component 140 may include a multilayer ceramic capacitor 141, a chip inductor, and/or an active die. For example, the first electronic component 140 may include at least a multilayer ceramic capacitor 141, but an embodiment thereof is not limited thereto. The multilayer ceramic capacitor 141 may include a multilayer ceramic capacitor (MLCC), but an embodiment thereof is not limited thereto. The active die may include a voltage regulator (VR), but an embodiment thereof is not limited thereto. The second electronic component 150 may include a silicon capacitor 151, but an embodiment thereof is not limited thereto. The silicon capacitor 151 may include a plurality of silicon through-vias (V), a plurality of first pads P1, a plurality of second pads P2, and the like, each of which may include copper (Cu), tungsten (W), and the like, but an embodiment thereof is not limited thereto. The conductive bump (S) may include a low-melting-point metal, such as solder, but an embodiment thereof is not limited thereto. The first electronic component 140 may be disposed in the first cavity (C1), and may be embedded in the first insulating layer 113 and/or the second insulating layer 116. The second electronic component 150 may be disposed in the second cavity (C2), and may be embedded in the first insulating layer 113. A thickness of the first electronic component 140 may be thicker than that of the second electronic component 150, but an embodiment thereof is not limited thereto. Each of the first and second electronic components 140 and 150 may be provided in plural, the above-described contents may be applied independently to each of the first and second electronic components 140 and 150.

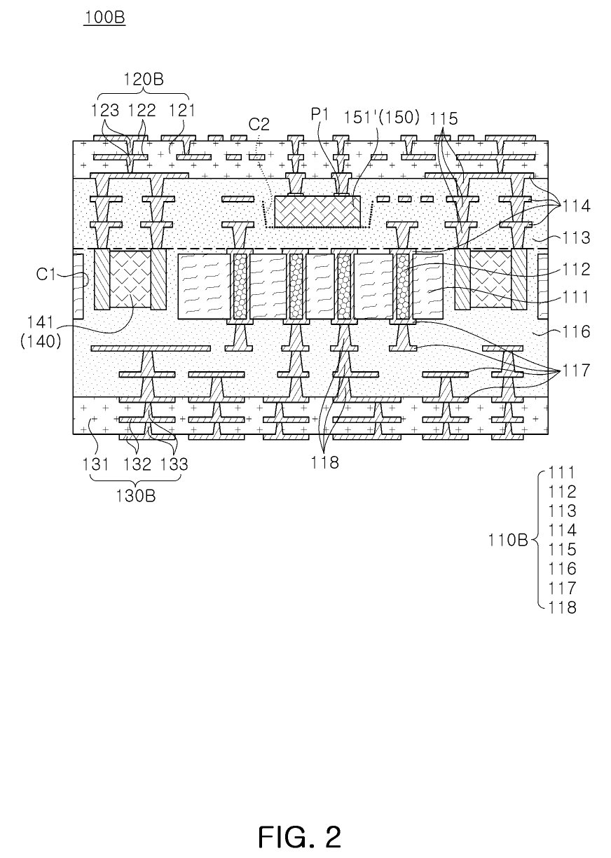

FIG. 2 is a cross-sectional view schematically illustrating a modified example of a printed circuit board.

Referring to FIG. 2, a printed circuit board 100B according to a modified example may include a second electronic component 150, for example, a silicon capacitor 151', including a first pad P1, but not including a silicon through-via (V) and a second pad P2, in the printed circuit board 100A according to the example described above. In addition, a wiring layer 114 may not be disposed on a bottom surface of the second cavity (C2), and a wiring via 115 may not be disposed directly below the bottom surface of the second cavity (C2). In addition, a conductive bump (S) may be omitted. For example, a lower surface of the second electronic component 150, for example, the silicon capacitor 151', may be attached to the bottom surface of the second cavity (C2). When attached, an adhesive film may be used, if necessary. In this case, the process difficulty may be further reduced and the process yield may be further improved. Other details thereof may be substantially the same as those described in the printed circuit board 100A according to the example described above. For example, a core portion 110B, a first build-up portion 120B, a second build-up portion 130B, a first electronic component 140, a second electronic component 150, and the like, of the printed circuit board 100B according to the modified example may be substantially identically applied to the core portion 110A, the first build-up portion 120A, the second build-up portion 130A, the first electronic component 140, the second electronic component 150, and the like, of the printed circuit board 100A according to the example described above, as long as they are not contradictory.

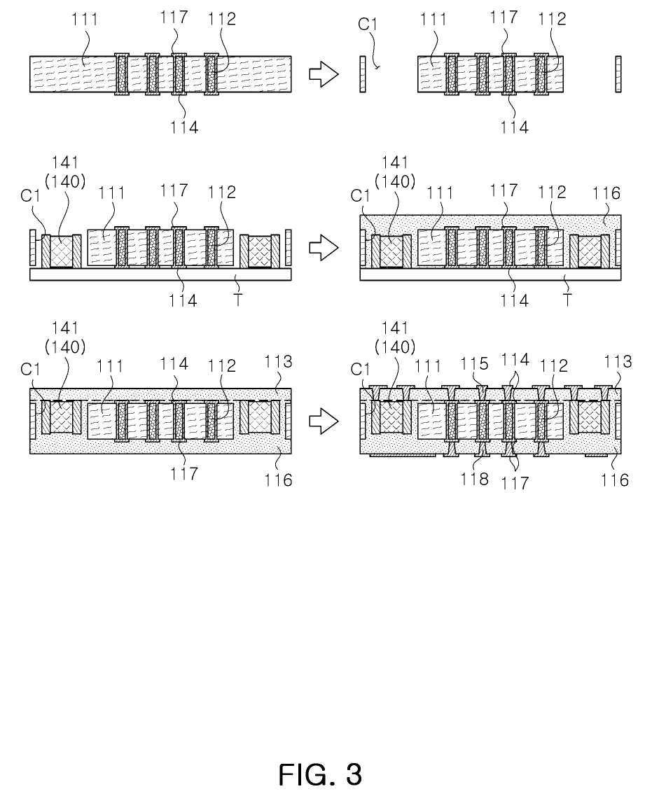

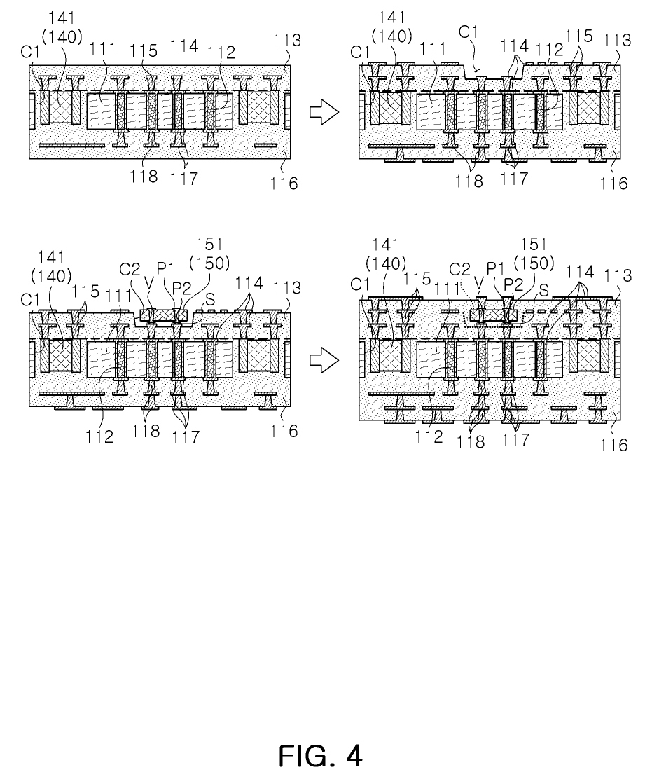

FIGS. 3 and 4 schematically illustrate a manufacturing example of a core portion.

Referring to FIGS. 3 and 4, first, a core layer 111 may be prepared using a copper-clad laminate, or the like, a plurality of through-holes may be formed in the core layer 111 using mechanical drilling, laser processing, blast processing, and/or chemical etching, and then a plurality of through-vias 112 and first and second wiring layers 114 and 117 may be formed using a plating process. Next, a plurality of first cavities (C1) may be formed in the core layer 111 by mechanical drilling, laser processing, and/or chemical etching. Next, a first electronic component 140, such as a multilayer ceramic capacitor 141, may be disposed in the plurality of first cavities (C1), respectively using tape (T). Next, a second insulating layer 116 covering the core layer 111 and the first electronic component 140, for example, the multilayer ceramic capacitor 141 and filling the first cavity (C1), may be formed on the tape (T). The second insulating layer 116 may be formed by laminating a prepreg (PPG), or the like. Next, the tape (T) may be removed, and the structure manufactured so far may be vertically inverted, and then a first insulating layer 22 covering the core layer 111 and the first electronic component 140, for example, the multilayer ceramic capacitor 141, may be formed. The first insulating layer 113 may be formed by laminating a prepreg (PPG), or the like. Next, via holes may be formed in the first and second insulating layers 113 and 116 by mechanical drilling, laser processing, and/or chemical etching, respectively, and then first and second wiring vias 115 and 118 may be formed by a plating process, and also first and second wiring layers 114 and 117 may be further formed. Next, the first and second insulating layers 113 and 116 may be further formed. Each of the first and second insulating layers 113 and 116 may be formed by laminating a prepreg (PPG), or the like. Next, a second cavity (C2) may be formed in the first insulating layer 113 using mechanical drilling, laser processing, blasting, and/or chemical etching. In addition, via holes can be formed in the first and second insulating layers 113 and 116 by mechanical drilling, laser processing, and/or chemical etching, respectively, and then the first and second wiring layers 114 and 117 may be formed by a plating process, and first and second wiring vias 115 and 118 may be further formed by a plating process. Next, a second electronic component 150, for example, a silicon capacitor 151, may be mounted in the second cavity (C2) using a conductive bump S. Next, a first insulating layer 113 covering the second electronic component 150, for example, the silicon capacitor 151 and filling the second cavity (C2) may be further formed. In addition, a second insulating layer 116 may be further formed. Each of the first and second insulating layers 113 and 116 may be formed by laminating a prepreg (PPG), or the like. In addition, via-holes can be formed in the first and second insulating layers 113 and 116 by mechanical drilling, laser processing, and/or chemical etching, and then the first and second wiring layers 114 and 117 and the first and second wiring vias 115 and 118 may be further formed by a plating process. Through a series of processes, a core portion 110A of the printed circuit board 100A according to the example described above may be manufactured. Thereafter, a build-up process may be performed on both sides of the core portion 110A using an Ajinomoto Build‑up Film (ABF), or the like to further form first and second build-up portions 120A and 130A, and in this case, the printed circuit board 100A according to the example described above may be manufactured. Meanwhile, in the manufacturing process described above, when the first wiring layer 114 and the first wiring via 115 are not formed in a region in which a bottom surface of the second cavity (C2) is disposed, and a silicon capacitor 151', instead of the silicon capacitor 151, is attached to the bottom surface of the second cavity (C2) as the second electronic component 150, a core portion 110B of the printed circuit board 100B according to the modified example described above may also be manufactured. Thereafter, a build-up process may be performed on both sides of the core portion 110B using an Ajinomoto Build‑up Film (ABF), or the like to further form first and second build-up portions 120B and 130B, and in this case, the printed circuit board 100B according to the modified example described above may be manufactured. Other details thereof may be substantially the same as those described in the printed circuit board 100A according to the example described above and the printed circuit board 100B according to the modified example.

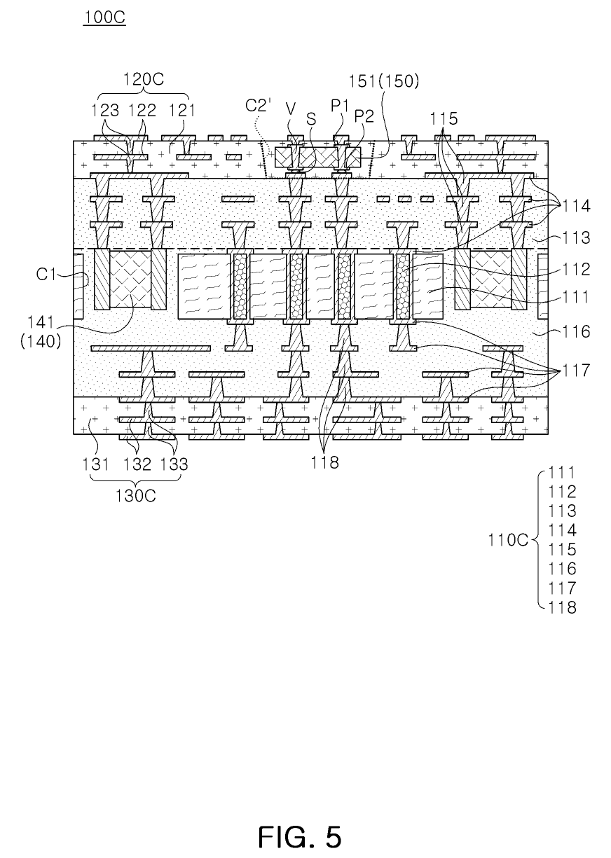

FIG. 5 is a cross-sectional view schematically illustrating another example of a printed circuit board.

Referring to FIG. 5, a printed circuit board 100C according to another example may have a second electronic component 150, for example, a silicon capacitor 151, embedded in a first build-up portion 120C, rather than a core portion 110C, in the printed circuit board 100A according to the example described above. For example, a second cavity (C2') may be formed in a first build-up layer 121 of the first build-up portion 120C, rather than a first insulating layer 113 of the core portion 110C. A position of the second cavity (C2') is not particularly limited, and may be formed in various positions within the first build-up portion 120C. For example, the first build-up layer 121 may have a second cavity (C2') penetrating through at least a portion of the first build-up layer 121 in the thickness direction, and the second electronic component 150, for example, the silicon capacitor 151, may be disposed in the second cavity (C2'). In addition, the first build-up layer 121 may fill at least a portion of the second cavity (C2') and cover at least a portion of the second electronic component 150, for example, the silicon capacitor 151. When a separate insulating material is used to fill the second cavity (C2'), if necessary, the insulating material may be seen as a portion of the first build-up layer 121. A second electronic component 150, for example, a silicon capacitor 151, may be easily embedded through the second cavity (C2'), and the second electronic component 150, for example, the silicon capacitor 151, may be disposed to be more adjacent to an active die mounted on a substrate. A first pad P1 of the second electronic component 150, for example, the silicon capacitor 151, may be connected to at least one third wiring via 123, thereby being electrically connected to at least a portion of a plurality of third wiring layers 122. In addition, a second pad P2 of a second electronic component 150, for example, a silicon capacitor 151, may be connected to a conductive bump (S), thereby being electrically connected to at least a portion of the plurality of first wiring layers 114 disposed on the bottom surface of the second cavity (C2'). For example, the second electronic component 150, for example, the silicon capacitor 151, may be electrically connected to the upper side and/or lower side. Other details thereof may be substantially the same as those described in the printed circuit board 100A according to the example described above. For example, a core portion 110C, a first build-up portion 120C, a second build-up portion 130C, a first electronic component 140, a second electronic component 150, and the like, of the printed circuit board 100C according to another example may be substantially identically applied to the core portion 110A, the first build-up portion 120A, the second build-up portion 130A, the first electronic component 140, the second electronic component 150, and the like, of the printed circuit board 100A according to the example described above, as long as they are not contradictory.

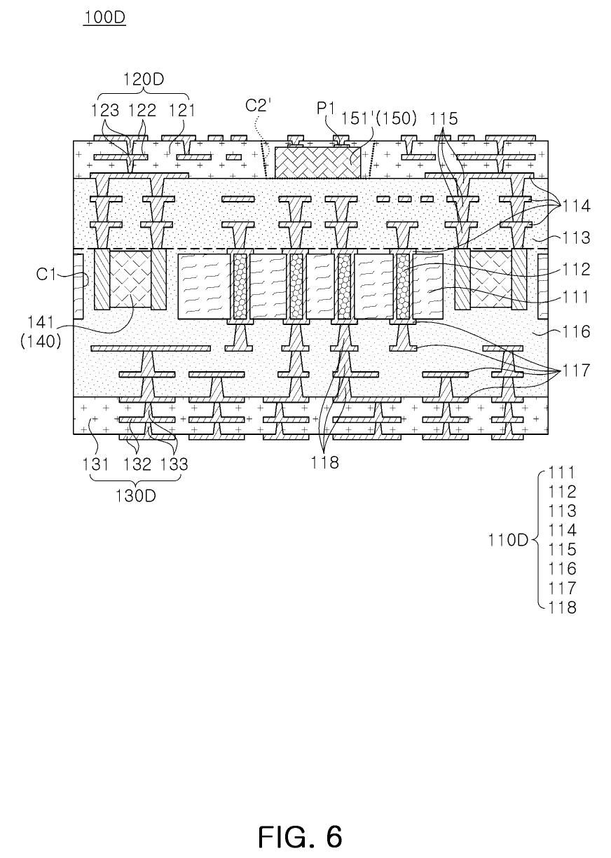

FIG. 6 is a cross-sectional view schematically illustrating another modified example of a printed circuit board.

Referring to FIG. 6, a printed circuit board 100D according to another modified example may include a second electronic component 150, for example, a silicon capacitor 151', including a first pad P1, but not including a silicon through-via (V) and a second pad P2, in the printed circuit board 100C according to another example described above. In addition, a wiring layer 114 may not be disposed on a bottom surface of the second cavity (C2'), and a wiring via 115 may not be disposed directly below the bottom surface of the second cavity (C2'). In addition, a conductive bump (S) may be omitted. For example, a lower surface of the second electronic component 150, for example, the silicon capacitor 151', may be attached to the bottom surface of the second cavity (C2'). When attached, an adhesive film may be used, if necessary. In this case, the process difficulty may be further reduced and the process yield may be further improved. Other details thereof may be substantially the same as those described in the printed circuit board 100A according to the example described above and the printed circuit board 100C according to another example. For example, a core portion 110D, a first build-up portion 120D, a second build-up portion 130D, a first electronic component 140, a second electronic component 150, and the like, of the printed circuit board 100D according to the modified example may be substantially identically applied to the core portion 110A, the first build-up portion 120A, the second build-up portion 130A, the first electronic component 140, the second electronic component 150, and the like, of the printed circuit board 100A according to the example described above, and the core portion 110C, the first build-up portion 120C, the second build-up portion 130C, the first electronic component 140, the second electronic component 150, and the like, of the printed circuit board 100A according to the example described above, as long as they are not contradictory.

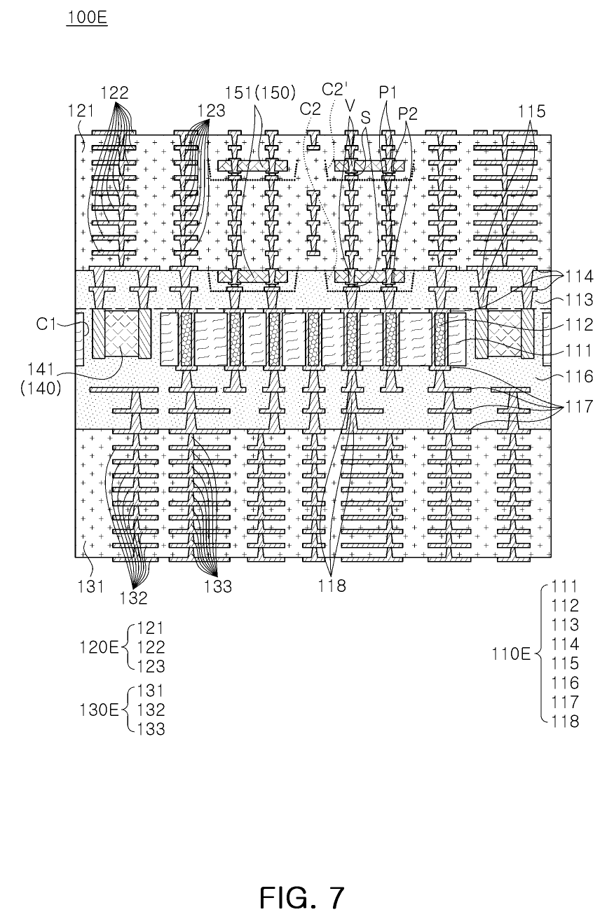

FIG. 7 is a cross-sectional view schematically illustrating another modified example of a printed circuit board.

Referring to FIG. 7, a printed circuit board 100E according to another example may be a combination of the structural features of the printed circuit board 100A according to the example described above and the structural features of the printed circuit board 100C according to another example described above. For example, a second electronic component 150, for example, a silicon capacitor 151, may be embedded in the core portion 110E and the first build-up portion 120E, respectively. For example, a plurality of 2-1 cavities (C2) may be formed in a first insulating layer 113 of the core portion 110E, a plurality of 2-2 cavities (C2') may be formed in a first build-up layer 121 of the first build-up portion 120E, and a second electronic component 150, for example, a silicon capacitor 151, may be disposed in each of the plurality of 2-1 and 2-2 cavities (C2 and C2'). The plurality of 2-1 cavities (C2) may be disposed at the same level. The plurality of 2-1 cavities (C2) may have the same or different shapes. The plurality of 2-2 cavities (C2') may be disposed at the same level. The plurality of 2-2 cavities (C2') may have the same or different shapes. The plurality of 2-1 cavities (C2) may be disposed on different levels from the plurality of 2-2 cavities (C2'). The plurality of 2-1 cavities (C2) may have the same or different shapes from the plurality of 2-2 cavities (C2'). Each of the plurality of 2-1 cavities (C2) may be filled with a first insulating layer 113, and a second electronic component 150, for example, a silicon capacitor 151 respectively disposed in the plurality of 2-1 cavities (C2), may be covered with the first insulating layer 113. However, an embodiment thereof is not limited thereto, and each of the plurality of 2-1 cavities (C2) may be filled with a first build-up layer 121, and the second electronic component 150, for example, the silicon capacitor 151 respectively disposed in the plurality of 2-1 cavities (C2), may be covered with the first build-up layer 121. If necessary, when a separate insulating material is used to fill the 2-1 cavity (C2), the insulating material may be seen as a portion of the first insulating layer 113 and/or the first build-up layer 121. Each of the plurality of 2-2 cavities (C2') may be filled with the first build-up layer 121, and a second electronic components 150, for example, a silicon capacitor 151 respectively disposed in the plurality of 2-2 cavities (C2'), may be covered with the first build-up layer 121. If necessary, when a separate insulating material is used to fill the 2-2 cavity (C2'), the insulating material may be seen as a portion of the first build-up layer 121. If necessary, the second electronic components 150 respectively disposed in the plurality of 2-1 cavities (C2) and/or the second electronic components 150 respectively disposed in the plurality of 2-2 cavities (C2') may also include a silicon capacitor 151' instead of the silicon capacitor 151. For example, the structural features of the printed circuit board 100B according to the modified example and/or the structural features of the printed circuit board 100E according to another modified example may be further combined. Other details thereof may be substantially the same as those described for the printed circuit board 100A according to the example described above, the printed circuit board 100B according to the modified example, the printed circuit board 100C according to another example, and the printed circuit board 100E according to another modified example. For example, a core portion 110E, a first build-up portion 120E, a second build-up portion 130E, a first electronic component 140, a second electronic component 150, and the like, of the printed circuit board 100E according to another example may be substantially identically applied to the core portion 110A, the first build-up portion 120A, the second build-up portion 130A, the first electronic component 140, the second electronic component 150, and the like, of the printed circuit board 100A according to the example described above, the core portion 110B, the first build-up portion 120B, the second build-up portion 130B, the first electronic component 140, the second electronic component 150, and the like, of the printed circuit board 100B according to the example described above, the core portion 110C, the first build-up portion 120C, the second build-up portion 130C, the first electronic component 140, the second electronic component 150, and the like, of the printed circuit board 100C according to the example described above, and the core portion 110D, the first build-up portion 120D, the second build-up portion 130D, the first electronic component 140, the second electronic component 150, and the like, of the printed circuit board 100D according to the example described above, as long as they are not contradictory.

In the present disclosure, the diameter, line width, thickness, width, length, pitch, depth, or the like, may be measured using a scanning microscope or optical microscope, respectively, based on a cross-section of a polished or cut printed circuit board. The cut cross-section may be a vertical cross-section or a horizontal cross-section, and each value can be measured based on the required cut cross-section. When the value is not constant, the value can be determined as an average value of the values measured at five random points. A width of an upper end portion and/or a lower end portion of a via or a cavity may be measured on a cross-section of the substrate cut in the thickness direction so as to cut a central axis of the via or the cavity. A depth of the via or the cavity may be measured as a distance from the upper end portion to the lower end portion of the via or the cavity in a cross-section of the substrate cut along the central axis of the via or cavity in the thickness direction.

In the present disclosure, the expression “covering” may include a case of at least partially covering as well as a case of covering completely, and may also include a case of covering not only directly but also indirectly. In addition, the expression “filling” may include a case of filling completely but also a case of at least partially filling, and may also include a case of approximately filling, and may include a case in which, for example, some pores, voids, or the like, exist.

In the present disclosure, determination may be performed by including process errors, positional deviations, errors at the time of measurement, which may occur substantially in a manufacturing process. For example, being substantially on the same level may include not only a case in which the thickness is completely constant, but also a case in which the thickness is approximately constant. In addition, having a shape substantially may include not only completely having such a shape, but also approximately having such a shape.

In the present disclosure, substantially the same material may mean not only completely the same material but also the same type of material. For example, a composition of the material may be substantially the same, but a specific composition ratio thereof may be slightly different.

In the present disclosure, the meaning on a cross-section may mean a cross-sectional shape when an object is vertically cut, or a cross-sectional shape when the object is viewed from the side. Also, the meaning on a plane may mean a planar shape when the object is horizontally cut, or a planar shape when the object is viewed from the top or the bottom.

In the present disclosure, a thickness direction was used to mean an upward direction and/or a downward direction with respect to a cross-section of a drawing. In addition, a lower side, a lower portion, and a lower surface were used to mean a downward direction with respect to the cross-section of the drawing, and an upper side, an upper portion, and an upper surface were used to mean an opposite direction thereof. However, this is a definition of direction for the convenience of explanation, and the scope of the claim is not specifically limited by the description of this direction, and the concept of upper/lower may be changed at any time.

In the present disclosure, the meaning of being connected is a concept including not only directly connected but also indirectly connected through an adhesive layer or the like. As used herein, ‘electrically connected’ means a conductive path exists between elements, whether directly or through one or more intermediate conductive structures (e.g., traces, vias, bumps). Physical contact is not required if a conductive path is present. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression “an example embodiment” used in the present disclosure does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, according to one of the effects of the present disclosure, a printed circuit board that can be applied to a large body product and can have a sufficient required capacitance, may be provided.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a core portion including a core layer, a first insulating layer at least partially disposed on an upper side of the core layer, a plurality of first wiring layers respectively disposed on or within the first insulating layer, a second insulating layer at least partially disposed on a lower side of the core layer, and a plurality of second wiring layers respectively disposed on or within the second insulating layer;
a first build-up portion including a first build-up layer disposed on the upper side of the core portion, and a plurality of third wiring layers respectively disposed on or within the first build-up layer;
a second build-up portion including a second build-up layer disposed on the lower side of the core portion, and a plurality of fourth wiring layers respectively disposed on or within the second build-up layer;
a first electronic component embedded in the core portion; and
a second electronic component embedded in at least one of the core portion or the first build-up portion, on a different level from that of the first electronic component,
wherein at least one of the first insulating layer or the second insulating layer includes a different insulating material from at least one of the first build-up layer or the second build-up layer.

2. The printed circuit board of claim 1, wherein the core layer, the first insulating layer, and the second insulating layer include an insulating resin, filler, and glass fiber, and the first build-up layer and the second build-up layer include an insulating resin and filler, but do not include glass fiber.

3. The printed circuit board of claim 2, wherein the core layer comprises an insulating material of a copper-clad laminate, each of the first insulating layer and the second insulating layer comprises a prepreg (PPG), and each of the first build-up layer and the second build-up layer comprises an Ajinomoto Build‑up Film (ABF).

4. The printed circuit board of claim 1, wherein the first electronic component comprises at least one of a multilayer ceramic capacitor, a chip inductor, or an active die, and the second electronic component comprises a silicon capacitor.

5. The printed circuit board of claim 4, wherein the silicon capacitor comprises a silicon through-via (V).

6. The printed circuit board of claim 1, wherein the core layer has a first cavity penetrating between an upper surface and a lower surface of the core layer in a thickness direction, and
the first electronic component is disposed in the first cavity, and
at least one of the first insulating layer or the second insulating layer fills at least a portion of the first cavity and covers at least a portion of the first electronic component.

7. The printed circuit board of claim 6, wherein the first insulating layer has a second cavity penetrating through at least a portion of the first insulating layer in the thickness direction,
the second electronic component is disposed in the second cavity, and
at least one of the first insulating layer or the first build-up layer fills at least a portion of the second cavity and covers at least a portion of the second electronic component.

8. The printed circuit board of claim 6, wherein the first build-up layer has a second cavity penetrating through at least a portion of the first build-up layer in the thickness direction,
the second electronic component is disposed in the second cavity, and
the first build-up layer fills at least a portion of the second cavity and covers at least a portion of the second electronic component.

9. The printed circuit board of claim 6, wherein the first insulating layer has a 2-1 cavity penetrating through at least a portion of the first insulating layer in the thickness direction,
the first build-up layer has a 2-2 cavity penetrating through at least a portion of the first build-up layer in the thickness direction,
wherein the second electronic component is disposed in the 2-1 cavity and the 2-2 cavity, respectively,
at least one of the first insulating layer or the first build-up layer fills at least a portion of the 2-1 cavity, and covers at least a portion of the second electronic component disposed in the 2-1 cavity, and
the first build-up layer fills at least a portion of the 2-2 cavity, and covers at least a portion of the second electronic component disposed in the 2-2 cavity.

10. The printed circuit board of claim 1, wherein the core portion further comprises a plurality of through-vias respectively disposed within the core layer, a plurality of first wiring vias respectively disposed within the first insulating layer, and a plurality of second wiring vias respectively disposed within the second insulating layer,
the first build-up portion further comprises a plurality of third wiring vias respectively disposed within the first build-up layer, and
the second build-up portion further comprises a plurality of fourth wiring vias respectively disposed within the second build-up layer.

11. The printed circuit board of claim 1, wherein each of the first insulating layer, the second insulating layer, the first build-up layer, and the second build-up layer is comprised of a plurality of layers.

12. A printed circuit board, comprising:
a core layer having a first cavity;
a plurality of through-vias respectively penetrating through at least a portion of the core layer;
an insulating layer disposed on the core layer, and having a second cavity;
a multilayer ceramic capacitor disposed in the first cavity, and embedded in the insulating layer;
a silicon capacitor disposed in the second cavity, and embedded in the insulating layer;
a plurality of wiring layers respectively disposed within the insulating layer; and
a plurality of wiring vias respectively penetrating through at least a portion of the insulating layer,
wherein the first cavity and the second cavity are disposed on different levels.

13. The printed circuit board of claim 12, wherein the silicon capacitor comprises a silicon through-via, a first pad connected to an upper side of the silicon through-via, and a second pad connected to a lower side of the silicon through-via.

14. The printed circuit board of claim 13, wherein the first pad is connected to at least a portion of the plurality of wiring layers through at least one of the plurality of wiring vias,
the second pad is connected to at least another portion of the plurality of wiring layers through a conductive bump, and
at least another portion of the plurality of wiring layers connected to the second pad is disposed on a bottom surface of the second cavity.

15. The printed circuit board of claim 12, wherein the first cavity comprises a plurality of first cavities, the multilayer ceramic capacitor is disposed in the plurality of first cavities, respectively, and the plurality of first cavities are disposed on the same level as each other.

16. The printed circuit board of claim 15, wherein the second cavity comprises a plurality of second cavities,
the silicon capacitor is disposed in the plurality of second cavities, respectively, at least a portion of the plurality of second cavities are disposed on the same level as each other, and
at least another portion of the plurality of second cavities are disposed on a different level from that of at least a portion of the plurality of second cavities.
